(19) United States
(12) Patent Application Publication
(10) Pub. No.: US 2011/0234214 A1
(43) Pub. Date: Sep. 29, 2011

(54) METAL DETECTOR SENSOR HEAD

(75) Inventor: Alexander Lewis Jones, West Croydon (AU)

(73) Assignee: MINELAB ELECTRONICS PTY LIMITED, Torrensville (AU)

(21) Appl. No.: 12/732,615

(22) Filed: Mar. 26, 2010

(30) Foreign Application Priority Data
Mar. 24, 2010 (AU) 2010901249

(51) Int. Cl. G01R 33/18

(52) U.S. Cl. 324/239

(57) ABSTRACT

A metal detector includes means for reducing the induction of eddy currents in conductive elements of a sensor head. The aim of this invention is to remove the effect of small pieces of conductive material, located within or close to the sensor head, being seen as sought targets as the sensor head is moved over magnetic matrix. The means is to surround the conductive material with material with high magnetic permeability and low losses in a time-varying magnetic field, say low-loss ferrite. This will prevent the reflected field from illuminating the conductive material so eddy currents are not generated.

### TECHNICAL FIELD

This invention pertains to metal detectors, particularly those that transmit time-varying magnetic fields to induce eddy currents in both ferrous and non-ferrous metallic targets, then detect the magnetic fields concomitant with the induced eddy currents.

### BACKGROUND OF THE INVENTION

Over many decades there have been improvements in the performance of metal detectors that transmit time-varying magnetic fields to illuminate sought targets. One motive for improvement is the desire for greater sensitivity to a greater range of targets. To this end, improvements such as higher dynamic range in the receive electronics, improvement in the ability to reject the signal from mineralised ground and increased sensitivity to smaller targets have been developed. At various times, an improvement has exposed deficiencies in aspects of the detector other than the electronics.

This invention deals with a deficiency in the design of coils, or sensing heads, of metal detectors. It has application in both continuous wave (CW) and pulse induction (PI) detectors.

The principle of detection of electrically conductive targets with a metal detector is that the detector transmits a time-varying magnetic field which induces eddy currents in conductive targets near the transmit (Tx) winding of the sensor head. Any such eddy current produces its own magnetic field that induces a signal in the receive (Rx) winding of the sensor head.

Any conductive target within range of the Tx field will have eddy currents induced in it. This includes any conductive elements of the sensor head.

It seems natural to suppose that small targets are harder to detect with metal detectors, than larger targets because they intercept less of the Tx field and, therefore, reflect less energy to the Rx winding. It is true that they generally do reflect less energy, but it is not only because of their lesser spatial cross-section; the degree to which a target accommodates and re-radiates the Tx field also depends upon the relationship between the frequency components of the Tx field and the dominant time constants (TC) of decay of eddy currents in the target, the “spectral cross-section” of the target in the Tx field.

The rates at which the induced eddy currents of targets decay, the TC, is determined by the shape, size, resistivity and magnetic permeability of the material. For simplicity in this description, the relative magnetic permeability of the targets will be assumed to be equal to one, a reasonable assumption for non-ferrous targets. The general trends for TCs of a target are:
the lesser volume of individual parts of a target produce shorter TCs in eddy currents;
the greater the resistivity of the constituent material, the shorter the TCs in eddy currents;
thin, widely distributed targets have shorter TCs than compact targets of the same volume.

The targets with shorter TCs respond better to Tx components of higher frequency, while targets with longer TCs respond better to Tx components of lower frequency. In CW detectors with discrete frequencies of Tx, targets of shorter TC will more readily reflect the Tx field of the higher frequencies.

In PI detectors, this translates to the delay between the ends of the Tx pulses and the samples taken of the Rx signal; the shorter that delay, the shorter the longest TC that is excluded from contributing to the samples taken of the Rx signal.

In order to have some chance of consistently detecting small targets with short time constants, such as fine grains of gold or the firing pins of minimum-metal landmines, in a variety of environments, a metal detector must have excellent rejection of ground mineralisation, large dynamic range in the Rx electronics, emit strong high-frequency components in the Tx field and they have the ability to demodulate signals of relatively high frequency as they are reflected by targets.

As mentioned previously, targets are not the only objects that are within the effective range of the Tx field of the sensor head. By necessity, the windings of a sensor head are made of highly conductive wire, usually copper, and in many coils are soldered to the leads that connect these windings to the control box of the metal detector. These solder joints are usually posited within the sensor head, that is within the Tx field. Through a phenomenon known as the proximity effect, the strands of wire in a winding loop have eddy currents generated in them by the magnetic field that the same winding generates. This interaction is not to be confused with that which generates the emf along the wires in a winding, as in a transformer.

The problem of eddy currents within the windings of the sensor head is addressed in U.S. Pat. No. 4,890,064. This patent is incorporated by reference in its entirety into this specification. The solution described in U.S. Pat. No. 4,890,064 is to use parallel strands of individually insulated wire whose diameters are small enough to prevent the generation of eddy currents that have TCs long enough to affect, significantly, the detection of sought targets.

Generally, the Tx and Rx are separate windings. The sensor heads of most detectors have the connection to the control box via a cable emerging from the sensor head with a pin-and-plug connection to be made at the control box. The connections of the windings to the conductors in the cable are often soldered joints located within the sensor head. The conglomerate of solder, winding conductor and cable conductor produces a volume of continuous conductor that can have a TC longer than those of some of the targets being sought with the detector. The signal produced by the joints affects the result of the demodulation of the Rx signal.

As long as the eddy currents are within conductors that are fixed, spatially, with respect to the windings, they are not noticeable to the user of a “motion” metal detector when the sensor head is motionless. The indicator of a motion detector responds to differences in the received signals and, as long as the magnitudes of the synchronous eddy currents are the same from one Tx cycle to the next, there is nothing for the detector to indicate.

Even if the sensor head is moving through space, there is not necessarily any reason for the magnitudes of these eddy currents to vary, as the time-varying Tx field affecting them remains substantially of constant magnitude.

When used over ground, metal detectors often have to deal with the effects of magnetic ground, that is ground that has a magnetic permeability much greater than 1, and often with complex permeability. These grounds occur in many places around the earth. Gold fields are renowned for having highly magnetic matrix that limits the effective sensitivity of metal detectors used there.

In such grounds, the signal in the Rx circuit, even when a target is present, is composed almost entirely of signal reflected by the ground, giving the advantage to those detectors with large dynamic range in the Rx electronics and with the ability to identify the signals of the magnetic ground and remove them in order to see the smaller target signal.

As the sensor head is moved over the ground, variations in the ground produce variations in the reflected field within the sensor head. These variations can be due to spatial variations in the concentration of magnetic material diffused through the matrix, different distances between the surface of the ground and the sensor head due to rough ground or some vertical movement of the sensor head, or changes in the nature of the magnetic permeability of the ground, or the presence of ‘hotrocks’.

Such effects can produce variations in the magnitudes of the eddy currents of conductive elements within the sensor head from one Tx cycle to the next, producing changing signals in the Rx winding, which will be interpreted by the detector as the detection of a sought target. This is especially true in modern detectors with large dynamic range, the ability to “balance” magnetic ground and sensitivity to targets with short time constants.

A detector whose Rx processes are adapted to cancel the effect of magnetic viscosity of the ground, be it a CW or PI detector, can suffer the effect described here. The effect is of the conductive elements; the role of the magnetic ground is merely to modulate the intensity of the Tx magnetic field to produce variations in the reflected field irradiating those elements.

### SUMMARY

According to an aspect of the present invention, there is provided a method for improving the sensitivity of a metal detector, the metal detector capable of transmitting transmit magnetic fields and receiving reflected magnetic fields for detecting a target in a ground, the method including:

identifying at least one electrically conductive element of the metal detector located within the effective ranges of the reflected magnetic fields, wherein an intensity of the reflected magnetic fields, entering the at least one electrically conductive element, changes because of the ground and/or the target, and the said intensity change adversely affects the sensitivity of the metal detector; and
redirecting the said reflected magnetic fields such that the intensity of the said reflected field entering the at least one electrically conductive element is attenuated.

According to another aspect of the present invention, there is provided a metal detector capable of transmitting transmit magnetic fields and receiving reflected magnetic fields for detecting a target in a ground, including:

at least one magnetic field redirecting element redirecting the said reflected magnetic fields such that the intensity of the reflected field entering at least one electrically conductive element of the metal detector, the at least one electrically conductive element posited within the effective ranges of the said reflected magnetic fields, is attenuated, wherein
a change of intensity of an un-attenuated reflected field entering the at least one electrically conductive element because of the ground and/or the target, adversely affects the sensitivity of the metal detector.

In one form, the magnetic field redirecting element is made of a material with a relative magnetic permeability greater than 1.

In one form, the relative magnetic permeability is a substantially real number over a predetermined range of operational frequencies.

In one form, the material is ferrite.

In one form, the metal detector includes a transmit coil for transmitting magnetic fields and a receive coil for receiving reflected magnetic fields; and wherein the at least one magnetic field redirecting element is substantially stationary with respect to the transmit coil and the receive coil.

In one form, the transmit coil and the receive coil are the same coil.

In one form, the at least one electrically conductive element of the metal detector is a volume of electrical solder.

In one form, the at least one electrically conductive element of the metal detector is an electrically conductive portion of an electronic circuit board.

The effective sensitivity of a metal detector might be reduced if the varying intensity of magnetic field reflected by magnetic matrices induces eddy currents of varying initial magnitudes in conductive components that are within the sensor head of the detector. This invention is a means of reducing the induction of eddy currents in conductive elements of a sensor head.

The aim of this invention is to remove the effect of small pieces of conductive material, located within or close to the sensor head, being seen as sought targets as the sensor head is moved over magnetic matrix. The means is to surround the conductive material with material with high magnetic permeability and low losses in a time-varying magnetic field, say low-loss ferrite. This will prevent the reflected field from illuminating the conductive material so eddy currents are not generated. The ferrite, with its low losses, responds to the time-varying field, a combination of directly transmitted field and that reflected by the matrix and any targets it contains, with such little loss as to make its response instantaneous as far as the metal detector is concerned. As long as its position with respect to the windings is fixed, it does not temporally modulate the field at any point in space.

In this invention, the motive is not the preservation of energy for the sake of it; were the Tx field not modulated by external magnetic or conductive matrices to produce variations in the reflected field, the generation of eddy currents in elements of the sensor head would have little effect upon the sensitivity of a motion metal detector.

### BRIEF DESCRIPTION OF THE DRAWINGS

FIG. 1 shows some of the elements of a sensor head relevant to this invention.

FIG. 2 shows the physical relationship between the reflected magnetic field and a solder joint within a sensor head. A stylistic depiction of eddy current is shown, within the body of the solder.

FIG. 3 shows an end-on, cross-section view of the effect of a tube of material with high magnetic permeability upon some of the field lines of a surrounding magnetic field. Note that the diagram is merely illustrative.

FIG. 4 depicts the temporal progression of the reflected field from a PI detector as modulated by a changing environment of magnetic material.

### DETAILED DESCRIPTION OF THE INVENTION

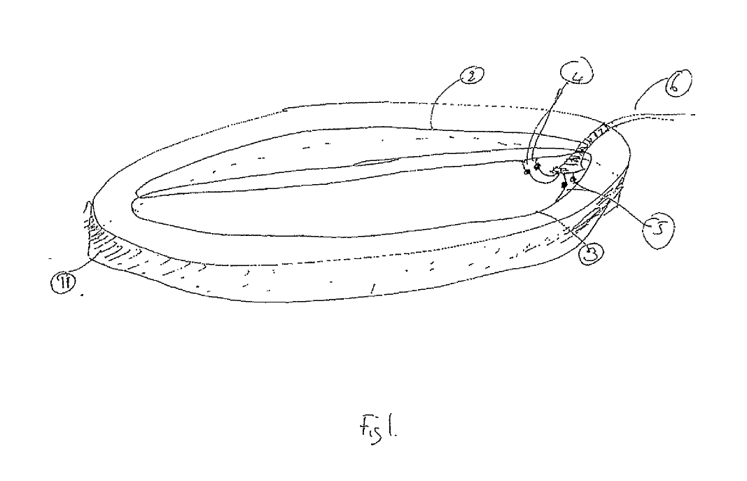

FIG. 1 shows a representation of an exemplar of a sensor head for a hand-held motion metal detector. The outer shell (1) houses the Rx winding (2), the Tx winding (3), the shape of which are one of many suitable for their purpose. The two free ends of the windings (2 & 3) are connected with soldered joints (4 & 5, respectively) to the cables with the lead (6) that connects the sensor head to the control box (not represented). The windings (2 & 3) are often made of Litzendraht wire, or at least fine, individually insulated, parallel strands of conductor, in order to prevent the generation of eddy currents with relatively long time constants in the windings, which is a preferred arrangement.

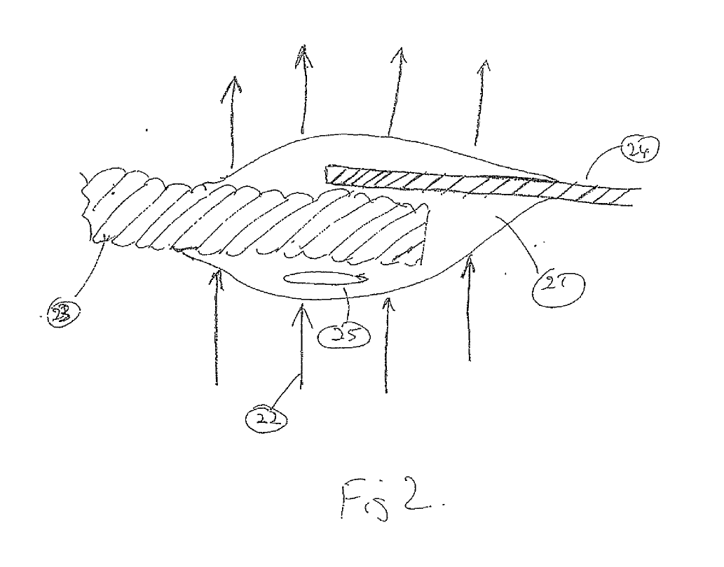

FIG. 2 shows a representation of a cross-section of a solder joint used within a sensor head. A time-varying magnetic field is represented by the field lines (22). The cable of the winding in the sensor head is shown (23), along with the cable to which it is connected (24) with the solder joint (21). A stylised representation of an eddy current, induced by the time-varying magnetic field (22), is shown (25). The eddy current (25) depends upon whether the intensity of the applied magnetic field (22) is increasing, or decreasing, with time, as well as the direction of the field.

Each strand of the cables (23 & 24) is coated with an electrical insulator, often a thin skin of polyurethane, reducing the tendency for a detector to see the cables and windings of the sensor head as a target. Where the ends of the winding and cable meet, depicted in FIG. 2, it is a requirement that the insulation of the individual strands is removed, in order that good electrical connection is made between the two and that the joint is as physically stable as it can be. Thus, the entire volume of the solder joint is one continuous body of electrically conductive metal, allowing the induction of eddy currents of sufficiently long time constant to be seen by a modern metal detector with sensitivity to small targets.

The detectable metal elements of a sensor head need not be the solder joints just described. Any piece of conductive metal, whether or not it carries an electrical current as part of some circuit, is capable of sustaining eddy currents induced by the reflected magnetic field. Another example of a detectable target might be a small electronic circuit embedded in the sensor head.

The nature of time-varying Tx fields of metal detectors is cyclic, that is the pattern of transmission is repeated, usually with a fundamental frequency between 100 Hz and 100 kHz. Nominally, the energy transmitted in each cycle is the same as in every other cycle. At any point in space, the magnitude of the magnetic field due to the Tx fields alone will be the same at every instance of an equivalent point in every Tx cycle. Such a field will induce eddy currents within conductive elements under the influence of the field, but the magnitudes of those eddy currents will be identical, from each cycle to the next, if the conductive elements are fixed in space with respect to the windings of the sensor head. Most metal detectors indicate detection only when they detect a difference in the reflected field. A situation in which the time-varying magnetic field, at a conductive element, has the same energy in each cycle will produce eddy currents that have the same magnitude and produce the same energy in their magnetic fields from each cycle to the next. A motion metal detector will not indicate a detection in this situation, given that the receive electronics is not driven into a non-linear state by the magnitude of the receive signals.

In order for a motion metal detector to indicate a detection due to conductive elements fixed with respect to the windings in its sensor head, there must be at those conductive elements, reflected fields with varying intensity due to the modulation of the time-varying Tx field. Such modulation can occur as the sensor head of an operating metal detector is moved in the vicinity of some material that generates a reflected magnetic field that is synchronous with the field transmitted by the detector. The material can be either electrically conductive, or be magnetic, or both.

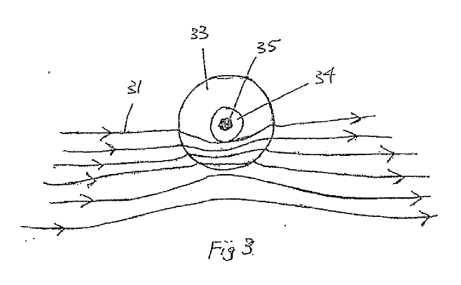

FIG. 3 shows an end-on, cross-section view of the effect of a tube of material with high magnetic permeability upon some of the field lines of a surrounding magnetic field impinging substantially perpendicular to the longitudinal axis of the tube. A time-varying magnetic field 31 is redirected from the space 34 by a shield 33. There would only be a negligible amount of eddy current induced by the magnetic field 31 in an electrically conductive element 35 posited in space 34. Even if there is such an eddy current, the magnetic field concomitant with the eddy current would be attenuated by the shield 33.

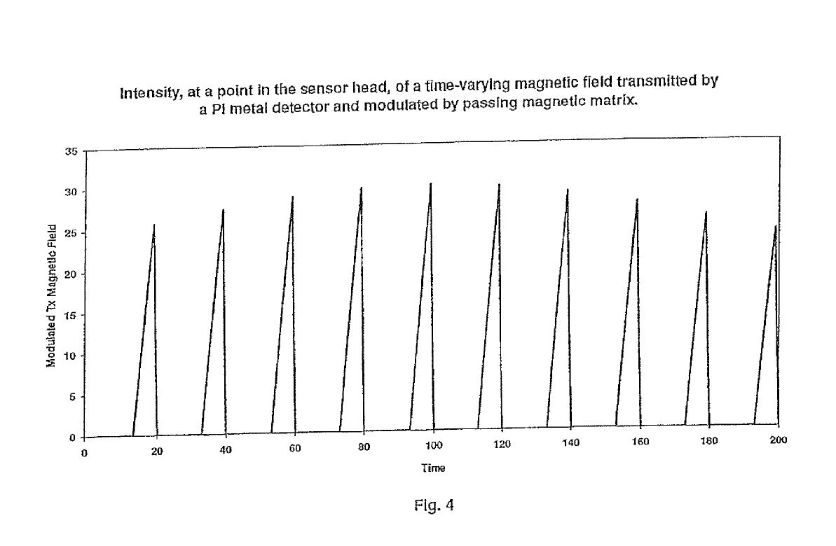

FIG. 4 is a simple graphical representation of a modulated time-varying field (the reflected field) at a point within the influence of the Tx winding. Strictly speaking, the modulation illustrated would have to be due to the influence of a volume of lossless magnetic material, but this invention does not rely on that condition in order to be efficacious.

The time-varying nature of the magnetic field is cyclic and is represented by the saw-tooth pulses of intensity. The modulation of the time-varying field is represented by the slowly varying amplitude of the pulses.

A typical situation, in use, where this modulation occurs is when metal detectors are used in fields whose soil or ground has an appreciable magnetic permeability. Such soils are common in, but not exclusive to, goldfields. Variations in the distance between Tx winding and the surface of the soil will effect the modulation; so will spatial variations in the magnetic permeability of the soil as the sensor head is passed over them.

It is common for magnetic soils or matrices to have a significant contribution through the effect of “magnetic viscosity”. This produces a remanent magnetism in the material after the applied magnetic field has been removed. The negation of the effects upon metal detectors of magnetic viscosity is the subject of much concentrated effort in the development of metal detectors.

In PI detectors, the decay of remanent magnetism during the receive periods of the Tx cycle induces signals in the Rx winding of a sensor head. If not negated through signal processing, these signals are strong enough to be confused with, or completely obscure, signals from sought targets. In many soils, the magnitude of the field reflected by the ground is orders of magnitude greater, at the sensor head, than the fields reflected by most sought targets. A field of such magnitude has a significant effect upon the magnitude of the nett synchronous magnetic field at the sensor head.

Again, in the case of PI detectors, the effect of induced eddy currents in elements of the sensor head, while the currents are induced synchronously with the Tx cycle, extends as they decay into the zero-field sections of the Tx cycle, during which time the signals in the Rx winding are processed for evidence of targets. The effect of this is to distort signals that would, otherwise, have been generated by the ground; this adversely affects the ability of a metal detector to negate the effects of magnetic viscosity.

This invention is a means of attenuating any reflected magnetic field at the conductive elements of a sensor head. This can be achieved by shielding such an element, from the reflected field, with a material with relative magnetic permeability (μr) greater than unity, and the material having a substantially zero imaginary component of its magnetic permeability as compared to the real component, that is, it has very low loss in the frequencies present in the time-varying magnetic Tx field.

Were the shielding material to have loss, or a complex magnetic permeability, it would, in effect, exhibit magnetic viscosity. Were the rate of decay of the remanent magnetisation of the material slow enough, as it is in mineralised ground, the modulation of the Tx field would produce a reflected field which modulates the magnitude of the remanent magnetisation of the shielding material, inducing a changing signal in the Rx of the metal detector. Any remanent magnetism of the shielding material must be of magnitude, during Rx demodulation periods of a detector, too small to elicit a detection.

Regardless of all else, the shield must be secured to some element of the sensor head that it is substantially fixed with respect to the windings within the sensor head. The shielding element distorts the Tx field; even small shifts in its relative position can induce detectable signals in the Rx winding.

In one embodiment of this invention, a suitable material is low-loss ferrite. A tube of ferrite, whose μr>1 (such as 10), can be posited with its longitudinal axis approximately perpendicular to the field lines of the Tx field. The object to be shielded is placed within the hollow of the tube such that its half-way point is approximately at the half-way point of the length of the tube. In this embodiment, the shielding tube should be long enough that the length of shielding tube beyond the extent of the shielded object is at least 1.5 times the inner diameter of the shielding tube.

In other embodiments of this invention, suitable materials of different shapes and sizes can be used, as long as the aim of attenuating the intensity of reflected field entering the at least one electrically conductive element can be achieved.

Many ferrites are made of material with non-zero conductivity. Like the electro-quasi-static shield incorporated in the sensor heads of many detectors, this conductivity is not great enough, nor the intended size of the magnetic shield big enough, for the shield to sustain eddy currents with TC long enough to be detected.

Generally speaking, the response of ferrite to changes in applied magnetic field is non-linear. As the intensity of the applied field increases, the relative magnetic permeability of the ferrite decreases. The rate of this decrease increases as the intensity of the applied field increases. In extreme cases, increasing the intensity of the applied field can reduce the relative permeability magnetic of the ferrite to near 1. As this relative magnetic permeability is reduced so does the effect of shielding the conductive elements of a sensing head from the reflected field.

In the case of shielding a solder joint connecting wires carrying electrical current, care must be taken to ensure that the current in the wires does not produce, at any time, a magnetic field that would magnetise the shield to the extent that its degree of magnetisation under the influence of applied fields becomes significantly non-linear. This would reduce the shielding effect of the material, by reducing its relative magnetic permeability. Generally, if a wire carries current through the shield, then another wire should carry the return current through the shield, in the opposing direction to the original current. In this manner the net magnetic field, from the conducting wires, within the shield is substantially zero.

All that remains to consider is the possibility that the shield is magnetically saturated by the applied Tx field. Whether the shield can be saturated depends upon the material of which the shield is made, the geometry of the Tx winding and the shield, and the intensity of the Tx field at the shield. Saturation can produce a significant reduction of the relative magnetic permeability of the shield while the field is applied. This effect is to be minimised when designing the shield, such as designing the shape, size, dimension, and orientation of the shield with respect to a metal detector.

The μᵣ of the material can be anything greater than 1, depending upon the degree of shielding required; as the μᵣ is increased, the likelihood of saturation increases. In the case of a ferrite tube with its longitudinal axis lying horizontal with respect to the plane of the Tx winding, there will be two components of B-field orientated in opposite directions through the material of the tube, substantially

B=μH

cancelling each other. The nett field in the ferrite, in this case, is much less than the equation suggests.

A detailed description of one or more preferred embodiments of the invention is provided above along with accompanying figures that illustrate by way of example the principles of the invention. While the invention is described in connection with such embodiments, it should be understood that the invention is not limited to any embodiment. On the contrary, the scope of the invention is limited only by the appended claims and the invention encompasses numerous alternatives, modifications, and equivalents. For the purpose of example, numerous specific details are set forth in the description above in order to provide a thorough understanding of the present invention. The present invention may be practiced according to the claims without some or all of these specific details. For the purpose of clarity, technical material that is known in the technical fields related to the invention has not been described in detail so that the present invention is not unnecessarily obscured.

Throughout this specification and the claims that follow unless the context requires otherwise, the words ‘comprise’ and ‘include’ and variations such as ‘comprising’ and ‘including’ will be understood to imply the inclusion of a stated integer or group of integers but not the exclusion of any other integer or group of integers.

The reference to any prior art in this specification is not, and should not be taken as, an acknowledgment or any form of suggestion that such prior art forms part of the common general knowledge of the technical field.

1. A method for improving the sensitivity of a metal detector, the metal detector capable of transmitting transmit magnetic fields and receiving reflected magnetic fields for detecting a target in a ground, the method including:
identifying at least one electrically conductive element of the metal detector located within the effective ranges of the reflected magnetic fields, wherein an intensity of the reflected magnetic fields, entering the at least one electrically conductive element, changes because of the ground and/or the target, and the said intensity change adversely affects the sensitivity of the metal detector; and
redirecting the said reflected magnetic fields such that the intensity of the said reflected field entering the at least one electrically conductive element is attenuated.

2. A metal detector capable of transmitting transmit magnetic fields and receiving reflected magnetic fields for detecting a target in a ground, including:
at least one magnetic field redirecting element redirecting the said reflected magnetic fields such that the intensity of the reflected field entering at least one electrically conductive element of the metal detector, the at least one electrically conductive element posited within the effective ranges of the said reflected magnetic fields, is attenuated, wherein
a change of intensity of an un-attenuated reflected field entering the at least one electrically conductive element because of the ground and/or the target, adversely affects the sensitivity of the metal detector.

3. A metal detector according to claim 2, wherein the magnetic field redirecting element is made of a material with a relative magnetic permeability greater than 1.

4. A metal detector according to claim 3, wherein the relative magnetic permeability is a substantially real number over a predetermined range of operational frequencies.

5. A metal detector according to claim 3, wherein the material is ferrite.

6. A metal detector according to claim 2, wherein the metal detector includes a transmit coil for transmitting magnetic fields and a receive coil for receiving reflected magnetic fields; and wherein the at least one magnetic field redirecting element is substantially stationary with respect to the transmit coil and the receive coil.

7. A metal detector according to claim 6, wherein the transmit coil and the receive coil are the same coil.

8. A metal detector according to claim 2, wherein the at least one electrically conductive element of the metal detector is a volume of electrical solder.

9. A metal detector according to claim 2, wherein the at least one electrically conductive element of the metal detector is an electrically conductive portion of an electronic circuit board.

10. A metal detector according to claim 4, wherein the material is ferrite.
